(19) United States
(12) Patent Application Publication
(10) Pub. No.: US 2024/0405507 A1
(43) Pub. Date: Dec. 5, 2024

(54) OPTOELECTRONIC COMPONENT AND METHOD FOR THE PRODUCTION THEREOF

(71) Applicant: ams-OSRAM International GmbH, Regensburg (DE)

(72) Inventors: Joerg Erich SORG, Regensburg (DE); Jan SEIDENFADEN, Neumarkt i.d Oberpfalz (DE); Markus HORN, Ergoldsbach (DE); Christoph WALTER, Regensburg (DE); Herbert BRUNNER, Sinzing (DE)

(73) Assignee: ams-OSRAM International GmbH, Regensburg (DE)

(21) Appl. No.: 18/710,405

(22) PCT Filed: Nov. 17, 2022
(86) PCT No.: PCT/EP2022/082324

§ 371 Date: May 15, 2024

(30) Foreign Application Priority Data
Nov. 19, 2021 (DE) 10 2021 130 369.9

(51) Int. Cl. H01S 5/0232; H01S 5/02255; H01S 5/02355; H01S 5/024

(52) U.S. Cl. CPC H01S 5/0232; H01S 5/02255; H01S 5/02355; H01S 5/02469

(57) ABSTRACT

The invention relates to an optoelectronic component including an electrically conductive first contact layer located on a carrier substrate, an electrically conductive platform that is located on the first contact layer and is formed integrally therewith, at least one laser diode that is located on the platform and is electrically connected thereto, and an electrically conductive second contact layer which is electrically coupled to the at least one laser diode. The height of the platform is such that the laser facet of the at least one laser diode is at such a vertical distance from the carrier substrate that a light cone emitted by the laser diode through the laser facet does not strike the carrier substrate within a predefined horizontal distance from the laser facet.

### CROSS-REFERENCE TO RELATED APPLICATIONS

The present application is a national stage entry from International Application No. PCT/EP2022/082324, filed on Nov. 17, 2022, published as International Publication No. WO 2023/089056 A1 on May 25, 2023, and claims the priority of German patent application No. 10 2021 130 369.9 dated Nov. 19, 2021, the disclosures of which are hereby incorporated by reference into the present application.

### FIELD

The present invention relates to an optoelectronic component, in particular a laser package with a reduced thermal resistance, and to a method of manufacturing an optoelectronic component.

### BACKGROUND

Laser diodes, and in particular high-power laser diodes, require good heat dissipation in order to achieve their full optical power. Therefore, these components are mounted on substrates (heat sinks) with high thermal conductivity. As the output power of laser diodes is constantly increasing, both the heat sink material and the mounting of the laser diodes on the heat sink material must be improved.

In previously known laser packages, the laser diode is arranged on a so-called submount, for example by means of a gold (Au) or tin (Sn) or gold-tin (AuSn) solder connection. The solder connection forms a first interface via which the heat generated by the laser diode must be dissipated. The submount on which the laser diode is arranged can, for example, consist of a ceramic material such as aluminum nitride (AlN) or silicon carbide (SiC) or of a ceramic coated with copper (direct-plated copper, DPC).

In laser packages known to date, the submount is also arranged on a particularly ceramic carrier substrate, for example by means of a gold (Au) or tin (Sn) or gold-tin (AuSn) solder compound, or a silver (Ag) or gold (Au) sinter paste. This solder or sintered compound forms a second interface via which the heat generated by the laser diode must be dissipated.

In order to reduce the overall thermal resistance (Rₜₕ) of the laser package and thus improve the heat dissipation of the laser diodes, attempts were made to use materials with improved thermal conductivity for the individual components and to achieve improved heat transfer at the interfaces of the individual components. Due to the many different materials and in particular the thermal interfaces of the laser package, such efforts only result in limited heat dissipation possibilities.

There is therefore a need to specify an optoelectronic component, in particular a laser package, with a reduced thermal resistance, as well as a method for manufacturing such an optoelectronic component, which counteracts at least one of the aforementioned problems.

### SUMMARY

This need is met by an optoelectronic component mentioned in claim 1. Claim 19 recites the features of a method of manufacturing an optoelectronic component according to the invention. Further embodiments are the subject of the subclaims.

The core idea of the invention is to reduce the number of thermal interfaces within the optoelectronic component, in particular laser packages. For this purpose, the submount/heat sink is integrated directly into the housing or an electrically conductive contact layer is formed in one piece with the submount on a carrier substrate of the laser package. By integrating the submount into the housing or by forming the submount in one piece with the electrically conductive contact layer on the carrier substrate of the laser package, the submount is replaced, so to speak, by a platform made of the same material as the electrically conductive contact layer, compared to previously known laser packages. This means that the interface between the housing or carrier substrate and the submount, via which the heat generated by the laser diode has to be dissipated, can be eliminated and the overall thermal resistance (Rₜₕ) of the laser package is reduced.

The integrated submount, e.g. in the form of a platform, consists in particular of the same material as the electrically conductive contact layer formed on the carrier substrate, in particular copper (Cu). An AuSn solder connection or an Ag or Au sinter paste is formed on the platform in order to arrange the laser diode on it and connect it electrically. The heat generated by the laser diode can thus be dissipated into the electrically conductive contact layer or the carrier substrate via only one interface between the platform and the laser diode.

Accordingly, the optoelectronic component according to the invention comprises an electrically conductive first contact layer arranged on a carrier substrate, an electrically conductive platform arranged on the first contact layer and integrally formed therewith, at least one laser diode, in particular a high-power laser diode, arranged on the platform and electrically connected thereto, and an electrically conductive second contact layer which is electrically coupled to the at least one laser diode. The platform has such a height that a laser facet of the at least one laser diode has such a vertical distance from the carrier substrate that a light cone emitted by the laser diode through the laser facet does not impinge on the carrier substrate within a predefined horizontal distance from the laser facet.

Without the platform, there would be a risk of the light beam emitted by the laser diode hitting the carrier substrate or another component of the optoelectronic component and being “clipped” by it. This risk exists in particular with downward-directed laser diodes, for example, where an optical element on the carrier substrate is arranged downstream in the beam path of the laser diode. Directed downwards means that the laser diode has a laser facet in the lower edge area of the laser diode and the light cone emitted by the laser diode not only radiates in a horizontal direction, but also radiates into an area below the laser diode with increasing horizontal distance from the laser facet due to the conical shape of the emitted light. However, the effect of beam clipping can be prevented by the platform having a corresponding height and by the optical element being arranged at a corresponding horizontal distance in front of the laser facet, as the light cone strikes the optical element in its entirety before it hits the carrier substrate and is clipped by it.

According to at least one embodiment, the at least one laser diode is arranged on the platform in such a way that the laser facet of the at least one laser diode lies outside the base surface of the platform. The laser facet therefore projects horizontally or laterally beyond the base surface of the platform. This also prevents beam clipping, as the light cone emitted by the laser diode cannot be cut off by the surface of the platform.

In addition to the advantage that the effect of beam clipping can be prevented or at least reduced by the height of the platform and the arrangement of the laser diode on the platform, the optoelectronic component according to the invention has the advantage that, due to the one-piece design of the platform with the first contact layer, heat formed in particular in the area of the underside of the laser diode can be dissipated better in the direction of the carrier substrate. One of the reasons for this is that a material with not only good electrical conductivity but also high thermal conductivity can be selected for the platform and the first contact layer, and because there is no interface between the platform and the first contact layer. The thermal resistance is thus significantly reduced compared to a laser package designed with a classic submount. It is therefore also possible to operate a high-power laser diode at its full optical power.

In addition, the one-piece design of the platform with the first contact layer results in a cost reduction for the optoelectronic component due to a simplified parts list (fewer components) and a simplified process sequence (fewer process steps) in the manufacture of the optoelectronic component.

According to at least one embodiment, the first contact layer and the platform have a high thermal conductivity, in particular a thermal conductivity greater than 350 W/mK, in addition to good electrical conductivity. For example, the first contact layer and the platform can be made of copper, which has a thermal conductivity of around 380 W/mK. In comparison, the ceramic base substrate of a classic submount, for example made of a ceramic material such as aluminum nitride (AlN), has a thermal conductivity of around 180 W/mK.

According to at least one embodiment, a projection surface of the platform viewed in a direction perpendicular to the carrier substrate is greater than or equal to a projection surface of the at least one laser diode viewed in a direction perpendicular to the carrier substrate. The base area of the platform can be correspondingly larger than or equal to the base area of the at least one laser diode.

According to at least one embodiment, a projection surface of the first contact layer viewed in a direction perpendicular to the carrier substrate is larger than a projection surface of the platform viewed in a direction perpendicular to the carrier substrate. The base area of the platform can be correspondingly smaller than the base area of the first contact layer. In particular, the platform can be designed in the form of an elevation on the first contact layer and form a step on the first contact layer in cross-section.

According to at least one embodiment, however, a projection surface of the first contact layer viewed in a direction perpendicular to the carrier substrate essentially corresponds to a projection surface of the platform viewed in a direction perpendicular to the carrier substrate. Accordingly, the first contact layer can be thickened by the platform over its entire surface and there is no local elevation due to the platform and therefore no step on the first contact layer.

According to at least one embodiment, the at least one laser diode is electrically connected to the second contact layer by means of at least one bonding wire and, in particular, by means of a plurality of bonding wires. In the case of a plurality of bonding wires, the advantage is that the heat generated in the laser diode can also be dissipated in an improved manner via the top side of the laser diode via the plurality of bonding wires (larger cross-section and reduced electrical resistance). In addition, several bond wires have the advantage that the probability of failure of the laser diode is reduced, as there is an increased probability of electrical contact between the laser diode and the second contact layer despite one or more defective bond wires.

According to at least one embodiment, the at least one laser diode is arranged on the platform by means of a sinter paste, a bonding material or a solder connection material and is electrically connected to the platform. The laser diode can accordingly be attached to the platform by means of thermocompression welding, a sintering process or a soldering process. For example, a gold (Au) or tin (Sn) or gold-tin (AuSn) solder connection, a silver (Ag) or gold (Au) sinter paste, or gold (Au) as contact material for a gold-gold (AuAu) interface can be used as materials.

According to at least one embodiment, there is only one interface between the first contact layer and the at least one laser diode. The interface is located in particular between the laser diode and the platform in the form of a solder, sintered or compression welded connection. In contrast, there is no interface between the platform and the first contact layer, and there are also no other layers, interfaces or materials between the first contact layer and the at least one laser diode.

According to at least one embodiment, the optoelectronic component further comprises an optical element which is arranged in the beam path of the light cone emitted by the at least one laser diode. A horizontal distance between the optical element and the laser facet of the laser diode is less than the predefined horizontal distance. This ensures that the full extent of the light cone emitted by the at least one laser diode strikes the optical element before it strikes the carrier substrate and is cut off by it.

According to at least one embodiment, the optical element is configured to deflect the light emitted by the at least one laser diode, in particular by approximately 90°. For example, the optical element is formed by a prism which is arranged in the beam path of the light cone emitted by the at least one laser diode and which is configured to deflect the light emitted by the at least one laser diode.

According to at least one embodiment, the carrier substrate has at least one electrically conductive contact via. In particular, the optoelectronic component comprises a first bottom contact and/or a second bottom contact on a side of the carrier substrate opposite the electrically conductive contact layer, wherein the first bottom contact is electrically connected to the first contact layer by means of a first electrically conductive contact via through the carrier substrate, and/or the second bottom contact is electrically connected to the second contact layer by means of a second electrically conductive contact via through the carrier substrate. As a result, the optoelectronic component can be controlled from the outside and can be supplied with electrical energy via the bottom contacts.

According to at least one embodiment, the carrier substrate is formed by an electrically insulating material. In particular, the carrier substrate can be formed by a ceramic material such as aluminum nitride (AlN) or silicon carbide (SiC).

According to at least one embodiment, however, the carrier substrate is formed in one piece with the first contact layer, in particular in the form of a lead frame. Accordingly, the carrier substrate can also be electrically conductive and be made of the same material as the first contact layer or the platform.

According to at least one embodiment, the optoelectronic component further comprises an electrically insulating frame which is arranged on the carrier substrate and which surrounds the platform and the at least one laser diode. In addition, the optoelectronic component may have an electrically conductive contact via within the frame or through the frame, which is electrically connected to the second contact layer.

According to at least one embodiment, the optoelectronic component also has a lid which is arranged on the frame and covers it. Together with the frame and the carrier substrate, the cover can enclose the laser diode in a closed space and hermetically encapsulate the optoelectronic component, for example.

A method of manufacturing an optoelectronic component, in particular an optoelectronic component according to at least one embodiment of the invention, comprises the steps of:
Providing a carrier substrate;
Applying a first layer of an electrically conductive contact material to the carrier substrate;
Applying a second layer of the electrically conductive contact material to the first layer in a region-wise manner so that it forms a platform integral with the first layer on the first layer; and
Arranging at least one laser diode on the platform, wherein the platform has such a height that a laser facet of the at least one laser diode has such a vertical distance from the carrier substrate that a light cone emitted by the laser diode through the laser facet does not impinge on the carrier substrate within a predefined horizontal distance from the laser facet.

The at least one laser diode can be arranged on the platform in such a way that the laser facet of the at least one laser diode lies outside the base surface of the platform, so that the laser facet projects horizontally or laterally beyond the platform.

According to at least one embodiment, the step of arranging the at least one laser diode may comprise compression welding, soldering or sintering the at least one laser diode onto the platform.

According to at least one embodiment, the step of applying a second layer of the electrically conductive contact material in certain areas comprises growing the electrically conductive contact material in certain areas. For example, the platform can be produced by electroplating, the upper side of which can optionally be planarized by an additional grinding and/or polishing process.

According to at least one embodiment, the method further comprises structuring the first layer of the electrically conductive contact material in such a way that it has a first electrically conductive contact layer and a second electrically conductive contact layer that is electrically insulated therefrom. The second layer of the electrically conductive contact material is then applied in sections to the first electrically conductive contact layer, thus creating the platform.

### BRIEF DESCRIPTION OF THE DRAWINGS

In the following, embodiments of the invention are explained in more detail with reference to the accompanying drawings. They show, in each case schematically,

FIG. 1 a sectional view of a laser package with a laser diode on a submount;

FIG. 2 a sectional view of an optoelectronic component according to some aspects of the proposed principle;

FIGS. 3A and 3B an isometric view and a sectional view of another embodiment of an optoelectronic component according to some aspects of the proposed principle;

FIG. 4 an isometric view of a further embodiment of an optoelectronic component according to some aspects of the proposed principle;

FIG. 5 a sectional view of a laser package with a laser diode on a carrier substrate with a metallic core;

FIGS. 6 to 8 in each case a sectional view of a further embodiment of an optoelectronic component according to some aspects of the proposed principle; and

FIG. 9 Process steps for manufacturing an optoelectronic component according to some aspects of the proposed principle.

### DETAILED DESCRIPTION

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the figures can be readily combined with each other without affecting the principle of the invention. Some aspects have a regular structure or shape. It should be noted that slight deviations from the ideal shape may occur in practice without, however, contradicting the inventive concept.

In addition, the individual figures, features and aspects are not necessarily shown in the correct size, and the proportions between the individual elements are not necessarily correct.

Some aspects and features are emphasized by enlarging them.

However, terms such as “above”, “above”, “below”, “below”, “larger”, “smaller” and the like are shown correctly in relation to the elements in the figures. It is thus possible to deduce such relationships between the elements on the basis of the figures.

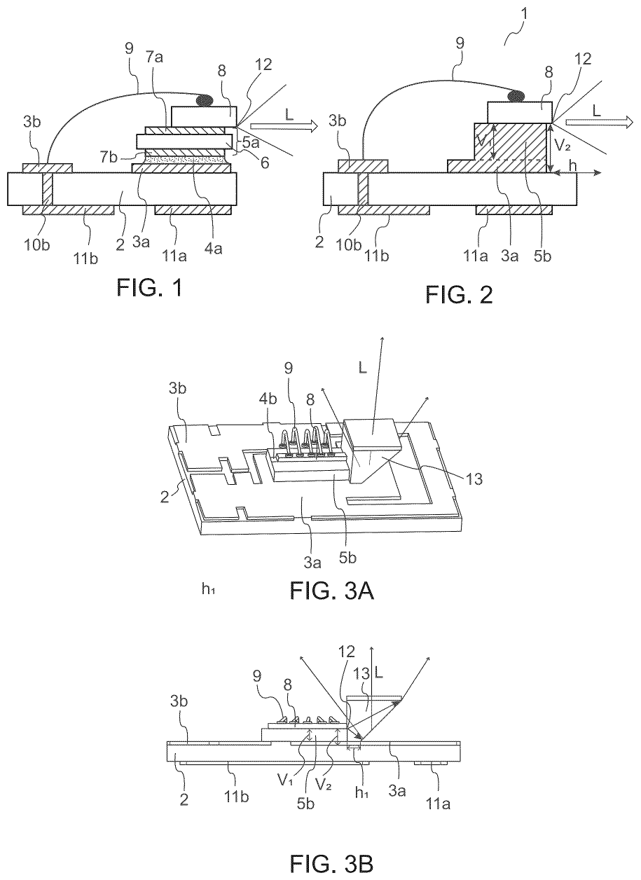

FIG. 1 shows a laser package comprising a ceramic carrier substrate 2, an electrically conductive first contact layer 3a arranged on the carrier substrate 2 and an electrically conductive second contact layer 3b arranged on the carrier substrate and electrically insulated from the first contact layer 3a. A submount 5 is applied to the first contact layer 3a by means of a first solder connection 4a, the submount 5 comprising a ceramic base substrate 6, an electrically conductive first contact surface 7a and an electrically conductive second contact surface 7b. A laser diode 8, which is electrically connected to the first contact layer 3a via the submount 5, the first solder connection 4a and the second solder connection not shown here, and which is electrically connected to the second contact layer 3b via a bonding wire 9, is applied to the submount 5 by means of a second solder connection not shown here.

The laser package also comprises contact vias 10 through the carrier substrate 2, a first bottom contact 11a, which is electrically connected to the first contact layer 3a via a first contact via not shown, and a second bottom contact 11b, which is electrically connected to the second contact layer 3b via a second contact via 10b. The laser package can be controlled from the outside via the bottom contacts 11 and can be supplied with energy.

The laser diode 8 is configured to emit laser light L, in particular in the form of a light cone, through a laser facet 12. The laser facet 12 is arranged in particular on a front side surface of the laser diode 8, especially in the area of the lower edge. On the one hand, this means that without the use of the submount 5, there is a risk that the light cone L emitted by the laser diode 8 will hit the carrier substrate and be “clipped” by it. On the other hand, the position of the laser facet 12 leads to increased heat generation in the area of the underside of the laser diode compared to the upper side, which must be transported away in the direction of the carrier substrate 2 via the submount 5. Due to the different materials of the submount 5 and in particular due to the two solder connections, efficient heat dissipation can hardly be realized, especially for high-power laser diodes.

FIG. 2 therefore suggests an improved optoelectronic component 1, in particular a laser package for high-power laser diodes, which has a lower thermal resistance and can therefore better dissipate the energy generated by the laser diode 8. Instead of the submount shown in FIG. 1, the optoelectronic component 1 has a platform 5b which is arranged on the first contact layer 3a and is formed in one piece with it. In particular, integral can mean that the platform 5b and the first contact layer 3a have the same material and merge into one another. In particular, the platform 5b and the first contact layer 3a can be made of copper. The platform 5b and the first contact layer 3a can thus be a continuous component, in particular one with very good electrical and thermal conductivity, which is divided into different areas. This is shown in FIG. 2 by the dashed line. The laser diode 8 is attached to the platform by means of a sintering paste or second solder connection (not shown) and is thus electrically and thermally connected to the platform.

Due to the one-piece design, heat generated in particular in the area of the underside of the laser diode 8 can be dissipated better in the direction of the carrier substrate, as the thermal resistance is significantly reduced compared to the laser package shown in FIG. 1 due to the high thermal conductivity of the platform 5b and the first contact layer 3a and due to the elimination of the interface between the platform 5b and the first contact layer 3a. It is therefore also possible to operate a high-power laser diode at its full optical power.

In addition, as already described at the beginning, the laser diode 8 is configured to emit laser light L, in particular in the form of a light cone, through a laser facet 12. The laser facet 12 is arranged in particular on a front side surface of the laser diode 8, in particular in the area of the lower edge. The laser facet is spaced at a vertical distance v₂ from the carrier substrate by the platform 5b and in particular by its height v₁. The light cone emitted by the laser diode 8 through the laser facet 12 therefore does not strike the carrier substrate 2 within a predefined horizontal distance h from the laser facet and is therefore not cut by the carrier substrate within this predefined horizontal distance h. Within this horizontal distance h, for example, an optical system can be arranged as described below, which deflects the uncut light cone. Without the platform, however, the light cone would be cut off and the efficiency of the optoelectronic component would be reduced.

In addition, the laser diode 8 is arranged on the platform in such a way that the laser facet 12 protrudes beyond a side surface of the platform 5b so that the laser facet floats almost freely in the air. This ensures that the light cone emitted by the laser diode 8 through the laser facet 12 does not impinge on the platform 5b and is not cut off by it.

FIGS. 3A and 3B show an isometric view and a sectional view of a further embodiment of an optoelectronic component 1 according to some aspects of the proposed principle. The optoelectronic component 1 has an optical element 13 in the form of a prism in the beam path of the light L emitted by the laser diode 8. The optical element 13 is configured to deflect the light cone L emitted by the laser diode 8, in particular by approximately 90°. Because the optical element 13 is arranged at a horizontal distance h₁ from the laser facet 12, whereby h₁ is smaller than the predefined horizontal distance h, the light cone L first strikes the optical element and is deflected by it before it is cut by the carrier substrate 2. The light cone therefore strikes the optical element completely and is not cut by the carrier substrate 2.

In addition, the optoelectronic component 1 of FIGS. 3A and 3B has several bonding wires 9, by means of which the laser diode 9 is electrically connected to the second contact layer 3b. This has the advantage that, on the one hand, the heat generated in the laser diode 8 can also be dissipated in an improved manner via the upper side of the laser diode 8 via the multiple bonding wires 9 (larger cross-section and reduced electrical resistance) and, on the other hand, that the probability of failure of the laser diode is reduced, since electrical contact between the laser diode and the second contact layer 3b still prevails despite a defective bonding wire 9. However, it is also conceivable that the laser diode can be supplied with a different amount of current by means of the various bonding wires in order to vary the intensity of the light L emitted by the laser diode.

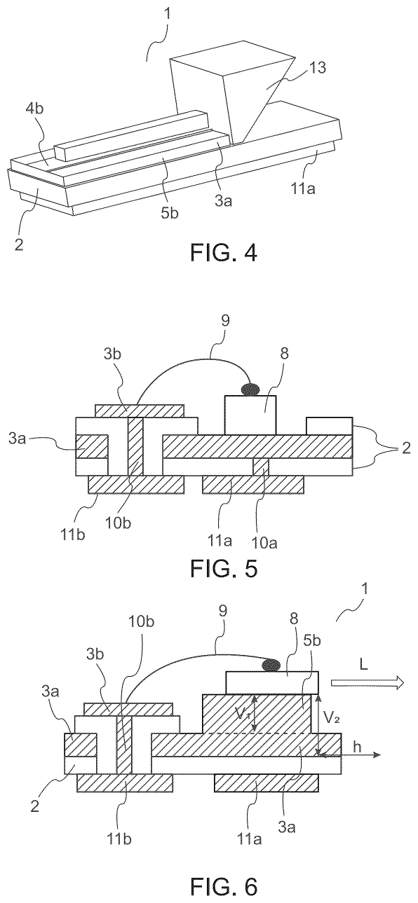

FIG. 4 shows an isometric view of a further embodiment example of an optoelectronic component 1. In contrast to the examples shown in FIGS. 2, 3A and 3B, the platform 5b of the embodiment example shown in FIG. 4 has a base area of the same size as the first contact layer 3a. A projection surface of the platform and the first contact layer 3a viewed in a vertical direction on the carrier substrate 2 are therefore essentially the same size. The platform 5b in combination with the first contact layer 3a thus does not have a step, in contrast to that in FIGS. 2, 3A and 3B, but essentially forms a thicker contact layer in comparison.

A laser diode 8 is again attached to the platform 5b by means of a second solder connection 4b or sinter paste and electrically connected to it. By means of an optical element, the light cone L emitted by the laser diode 8 can also be deflected so that the light L emitted by the laser diode in the horizontal direction emerges from the optoelectronic component 1 in the vertical direction.

FIG. 5 shows another laser package with a laser diode 8 on a carrier substrate 2 with a metallic core. The metallic core is formed by a first contact layer 3a. Electrically insulated vias 10 are also formed through the carrier substrate 2 and through the first contact layer 3a. A first contact via 10a electrically connects a first bottom contact 11a to the first contact layer 3a and a second contact via 10b connects a second bottom contact 11b to a second contact layer 3b. The second contact layer 3b is arranged in a different plane than the first contact layer 3a and is electrically insulated from it by means of the material of the carrier substrate. The laser diode 8 is electrically connected to the second contact layer 3b by means of a bonding wire 9.

The laser diode 8 is arranged directly on the first contact layer 3a and thus not on an elevation, so that there is a risk that a light cone emitted by the laser diode 8 strikes the carrier substrate 2 or the first contact layer 3a and is cut by it.

FIG. 6 therefore proposes an improved optoelectronic component 1 in this respect, in particular a laser package for high-power laser diodes. A platform 5b is arranged on the first contact layer 3a and formed in one piece with the first contact layer 3a, on which the laser diode is arranged. Due to the height v₁ of the platform 5b, the laser facet is spaced at a vertical distance v₂ from the carrier substrate. The light cone emitted by the laser diode 8 through the laser facet 12 therefore does not impinge on the carrier substrate 2 or the first contact layer 3a within a predefined horizontal distance h from the laser facet and is therefore not cut by the carrier substrate or the first contact layer 3a within this predefined horizontal distance h.

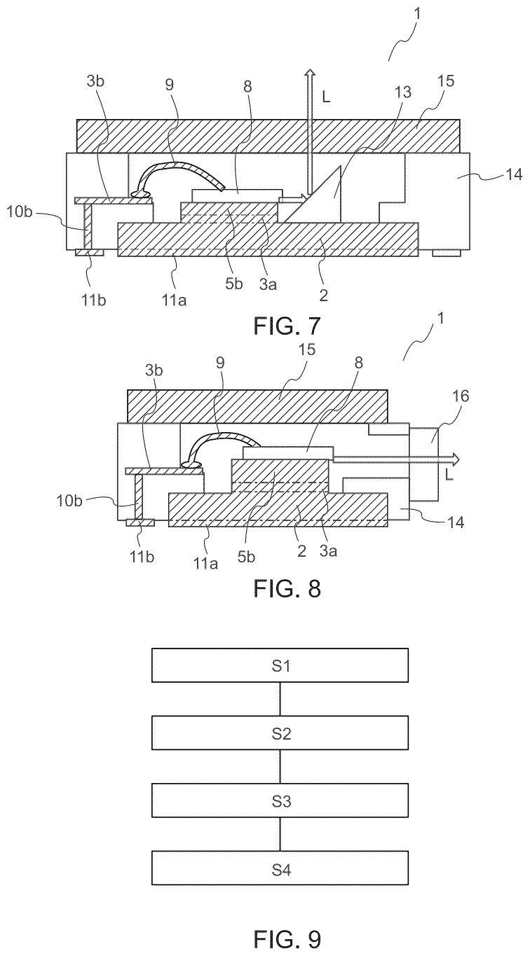

FIGS. 7 and 8 each show a sectional view of a further embodiment of an optoelectronic component 1 according to some aspects of the proposed principle. The carrier substrate 2 is formed from the same material as the first contact layer 3a and the platform 5b and is formed integrally therewith. The carrier substrate 2, the first contact layer 3a, the platform and also the first bottom contact 11a can thus be a continuous, in particular very good electrically and thermally conductive, component which is divided into different areas. This is shown in the two figures by means of the dashed line.

A frame 14 is formed on the carrier substrate 2, which surrounds both the platform 5b and the laser diode 8 arranged on the platform. The second electrically conductive contact layer 3b is formed within the frame 14 and is electrically connected to the second bottom contact 11b by means of a second contact via 10b.

The optoelectronic component 1 in FIG. 7 also has a cover 15 which is transparent to at least the light L emitted by the laser diode 8 and deflected by the optical element 13 and which, together with the frame 14, encloses the laser diode 8 in a closed space. For example, the frame 14 together with the cover 15 can also hermetically seal the optoelectronic component 1.

In contrast, the optoelectronic component 1 in FIG. 8 does not have an optical element 13 which deflects the light L emitted by the laser diode 8 in the horizontal direction. Instead, a window is formed in the frame 15 of the optoelectronic component 1 in the beam path of the laser diode 8, which is covered with a glazing 16 that is transparent to at least the light L emitted by the laser diode 8. The light emitted by the laser diode in the horizontal direction can therefore also leave the optoelectronic component 1 in this direction. In contrast to the previous embodiment example, the cover 15, which together with the frame 14 encloses the laser diode 8 in a closed space, may not be transparent and may, for example, be formed by a metal.

FIG. 9 shows process steps for manufacturing an optoelectronic component, in particular an optoelectronic component according to some aspects of the proposed principle. In a first step S1, a carrier substrate is provided, to which a first layer of an electrically conductive contact material is applied in a second step S2. In a further step S3, a second layer of the electrically conductive contact material is then applied to the first layer of the electrically conductive contact material, at least in certain areas, so that it forms a platform on the first layer that is formed integrally with the first layer. Then, in a further step S4, at least one laser diode is attached to the platform, in particular by means of a solder connection or a sintering paste, and electrically connected to it. The platform has such a height that the laser facet of the at least one laser diode has such a vertical distance from the carrier substrate that a light cone emitted by the laser diode through the laser facet does not impinge on the carrier substrate within a predefined horizontal distance from the laser facet.

1. An optoelectronic component comprising:
an electrically conductive first contact layer arranged on a carrier substrate;
an electrically conductive platform arranged on the first contact layer which is made in one piece with the first contact layer;
at least one laser diode arranged on the platform being electrically connected to the at least one laser diode; and
an electrically conductive second contact layer which is electrically coupled to the at least one laser diode,
wherein the platform has such a height that a laser facet of the at least one laser diode has such a vertical distance from the carrier substrate that a light cone emitted by the laser diode through the laser facet does not impinge on the carrier substrate within a predefined horizontal distance from the laser facet, and
wherein the projection area of the first contact layer viewed in the direction perpendicular to the carrier substrate is larger than the projection area of the platform viewed in the direction perpendicular to the carrier substrate.

2. The optoelectronic component according to claim 1, wherein the at least one laser diode is arranged on the platform in such a way that the laser facet of the at least one laser diode lies outside the base surface of the platform.

3. The optoelectronic component according to claim 1, wherein the first contact layer and the platform have a high thermal conductivity, in particular a thermal conductivity greater than 350 W/mK.

4. The optoelectronic component according to claim 1, wherein the projection area of the platform viewed in the direction perpendicular to the carrier substrate is greater than or equal to the projection area of the at least one laser diode viewed in the direction perpendicular to the carrier substrate.

5. The optoelectronic component according to claim 1, wherein the at least one laser diode is electrically connected to the second contact layer by means of at least one bonding wire and in particular by means of a plurality of bonding wires.

6. The optoelectronic component according to claim 1, wherein the at least one laser diode is arranged on the platform by means of a sintering paste or a bonding material and is electrically connected thereto.

7. The optoelectronic component according to claim 1, wherein only one interface exists between the first contact layer and the at least one laser diode.

8. The optoelectronic component according to claim 1, further comprising an optical element which is arranged in the beam path of the light cone emitted by the at least one laser diode, wherein a horizontal distance of the optical element from the laser facet of the laser diode is less than the predefined horizontal distance.

9. The optoelectronic component according to claim 8, wherein the optical element is configured to deflect the light emitted by the at least one laser diode, and wherein the optical element is formed in particular by a prism.

10. The optoelectronic component according to claim 1, wherein the carrier substrate comprises at least one electrically conductive contact via.

11. The optoelectronic component according to claim 10, further comprising a first bottom contact and a second bottom contact on a side of the carrier substrate opposite the electrically conductive first contact layer, wherein the first bottom contact is electrically connected to the first contact layer by means of a first electrically conductive contact via through the carrier substrate, and the second bottom contact is electrically connected to the second contact layer by means of a second electrically conductive contact via through the carrier substrate.

12. The optoelectronic component according to claim 1, wherein the carrier substrate is formed by an electrically insulating material.

13. The optoelectronic component according to claim 1, wherein the carrier substrate is formed integrally with the first contact layer, in particular in the form of a lead frame.

14. The optoelectronic component according to claim 13, further comprising an electrically insulating frame which is arranged on the carrier substrate and which surrounds the platform and the at least one laser diode.

15. The optoelectronic component according to claim 13, wherein the second contact layer comprises an electrically conductive contact via through the frame.

16. The optoelectronic component according to claim 13, further comprising a cover arranged on and covering the frame.

17. A method for manufacturing an optoelectronic component comprising:
providing a carrier substrate;
applying a first layer of an electrically conductive contact material to the carrier substrate;
applying a second layer of the electrically conductive contact material on the first layer in a region-wise manner so that it forms a platform integral with the first layer on the first layer; and
arranging at least one laser diode on the platform,
wherein the platform has such a height that a laser facet of the at least one laser diode has such a vertical distance from the carrier substrate that a light cone emitted by the laser diode through the laser facet does not impinge on the carrier substrate within a predefined horizontal distance from the laser facet, and
wherein a projection area of the first contact layer viewed in a direction perpendicular to the carrier substrate is larger than a projection area of the platform viewed in the direction perpendicular to the carrier substrate.

18. The method according to claim 17, wherein the at least one laser diode is arranged on the platform in such a way that the laser facet of the at least one laser diode is located outside a base surface of the platform.

19. The method according to claim 17, wherein arranging the at least one laser diode comprises compression welding or sintering the at least one laser diode onto the platform.

20. The method according to claim 17, wherein applying the second layer region-wise comprises growing the electrically conductive contact material region-wise.

21. The method according to claim 17, further comprising patterning the first layer of the electrically conductive contact material such that it comprises a first electrically conductive contact layer and a second electrically conductive contact layer electrically insulated therefrom, wherein the region-wise application of the second layer of the electrically conductive contact material is performed on the first electrically conductive contact layer.
